(19) United States
(12) Patent Application Publication
(10) Pub. No.: US 2025/0226831 A1
(43) Pub. Date: Jul. 10, 2025

(54) DEVICE FOR RECOVERING DIGITAL CLOCK DATA

(71) Applicant: LX SEMICON CO., LTD., Daejeon (KR)

(72) Inventors: Jong Suk LEE, Daejeon (KR); Seok Jae OH, Daejeon (KR)

(73) Assignee: LX SEMICON CO., LTD., Daejeon (KR)

(21) Appl. No.: 19/013,726

(22) Filed: Jan. 8, 2025

(30) Foreign Application Priority Data
Jan. 8, 2024 (KR) 10-2024-0003187
Nov. 28, 2024 (KR) 10-2024-0173498

(51) Int. Cl. H03L 7/099; H03L 7/18

(52) U.S. Cl. CPC H03L 7/0991; H03L 7/18

(57) ABSTRACT

A digital clock data recovery device for recovering a clock and data in a data signal includes a phase difference compensation unit configured to selectively output an upper bit value and a lower bit value of a phase difference value between a first input signal and a second input signal according to a condition based on a range of the phase difference value, a digital loop filter configured to receive an output of the phase difference compensation unit; and a digital controlled oscillator configured to transfer a feedback signal to the phase difference compensation unit based on an output value of the digital loop filter.

### CROSS-REFERENCE TO RELATED APPLICATIONS

This application claims the priorities of Korean Patent Application No. 10-2024-0003187 filed on Jan. 8, 2024, and Korean Patent Application No. 10-2024-0173498 filed on Nov. 28, 2024, which are hereby incorporated by reference in their entirety.

### BACKGROUND

### Field of the Disclosure

The present disclosure relates to a digital clock recovery device.

### Description of the Background

With the recent advancements in communication technology, the need for high-speed data transmission is also increasing. For this purpose, a serial communication method is used to transmit data at high speed. Serial communication may be used in various communication processes, including communication between independent devices, communication between components in a system, and data transfer within an integrated circuit.

A clock data recovery circuit that detects the phase of a clock embedded in serial data, generates recovered clocks from the serial data, and generates recovered data from the serial data using the recovered clocks may be used in various devices that transmit and receive data in a serial communication method.

In such a communication method, a function to recover clocks from data and to align the phases of the recovered clocks is required. To recover a clock and data from a data signal, the clock is first recovered and then the data is recovered using the recovered clock. To this end, the frequency and phase of the clock may be locked.

In the data recovery process, it is desirable to reduce a time to lock the frequency and phase, the so-called locking time, but limitations may arise with respect to the size of a circuit.

Therefore, there is a need for a method to reduce the locking time while efficiently configuring the size and configuration of the circuit.

### SUMMARY

Accordingly, the present disclosure is to provide a digital clock data recovery device which operates with an embedded signal without a reference clock and a method therefor.

The present disclosure is also to provide a digital clock data recovery device usable in various protocols and a method therefor.

Further, the present disclosure is to provide a digital clock data recovery device with reduced locking time and a method therefor.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a digital clock data recovery device for recovering clock and data from a data signal may include a phase difference compensation unit that selectively outputs an upper bit value and a lower bit value of a phase difference value between a first input signal and a second input signal according to a condition based on a range of the phase difference value, a digital loop filter DLF that receives the output of the phase difference compensation unit, and a digital controlled oscillator DCO that transfers a feedback signal to the phase difference compensation unit 101 based on the output of the digital loop filter.

In another an aspect of the present disclosure, a digital clock data recovery device for recovering a clock and data in a data signal may include a Time-to-Digital Converter (TDC) that compares phase differences between a reference signal and data signals to output a first bit value, a digital loop filter that receives an output value of the TDC, a digital controlled oscillator that oscillates a signal according to an output value of the digital loop filter, and a phase detector that accumulates a number of phase differences between the data signal and an output of the digital controlled oscillator and output a second bit value.

According to an aspect of the present disclosure, it is possible to implement a clock data recovery device capable of operating with a signal with an embedded clock without a reference clock as a fully digital circuit. As described above, the clock data recovery device is implemented with a digital circuit, which has the advantage of short locking time. Furthermore, it is highly scalable to process changes.

As described above, it is possible to configure a divider capable of changing a dividing ratio between the input path and the feedback path, respectively, be used in various protocols.

On the other hand, to increase the resolution, for example, a total of 9 bits of data may be used, but the TDC may be implemented with only the upper bits (e. g., 6 bits), which may reduce the size of the circuit.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a block diagram illustrating a clock data recovery device according to an example aspect of the present disclosure.

FIG. 2 is a timing diagram illustrating operation of a clock data recovery device according to an example aspect of the present disclosure.

FIG. 3 is a flowchart showing the operation of a clock data recovery device according to an aspect of the present disclosure.

FIG. 4 is a block diagram illustrating a digital controlled oscillator of a clock data recovery device according to an example aspect of the present disclosure.

FIG. 5 is a block diagram illustrating a TDC of a clock data recovery device according to an example aspect of the present disclosure.

FIG. 6 is a block diagram showing a phase detector of a clock data recovery device according to an example aspect of the present disclosure.

FIG. 7 and FIG. 8 are timing diagrams for describing the operation of the phase detector.

FIG. 9 is a block diagram illustrating a divider unit of a clock data recovery device according to an example aspect of the present disclosure.

FIGS. 10 to 12 are timing diagrams of a divider unit.

### DETAILED DESCRIPTION

Hereinafter, the aspects disclosed herein will be described in detail with reference to the accompanying drawings, and the same or similar elements are designated with the same numeral references regardless of the numerals in the drawings and their redundant description will be omitted. The suffixes “module” and “unit or portion” for components used in the following description are merely provided only for facilitation of preparing this specification, and thus they are not granted a specific meaning or function.

In addition, when it is determined that the detailed description of the related known technology may obscure the gist of aspects disclosed herein in describing the aspects, a detailed description thereof will be omitted. Further, it should be noted that the accompanying drawings are only for easy understanding of the aspects disclosed in the present specification, and should not be construed as limiting the technical spirit disclosed in the present specification by the accompanying drawings.

Furthermore, although each drawing is described for convenience of explanation, it is also within the scope of the present disclosure for a person skilled in the art to implement another aspect by combining at least two or more drawings.

It is also understood that when an element, such as a layer, region, or substrate, it is referred to as being “on” another element, it may be directly present on the other element or intervening elements in between.

Terms such as first and second are used to distinguish one component from another component, and the components are not limited by the above-mentioned terms.

As used herein, singular forms may include plural forms as well unless the context clearly indicates otherwise.

In each step, identification symbols are used for convenience of description and the identification symbols do not describe the order of the steps and the steps may be performed in a different order from the described order unless the context clearly indicates a specific order.

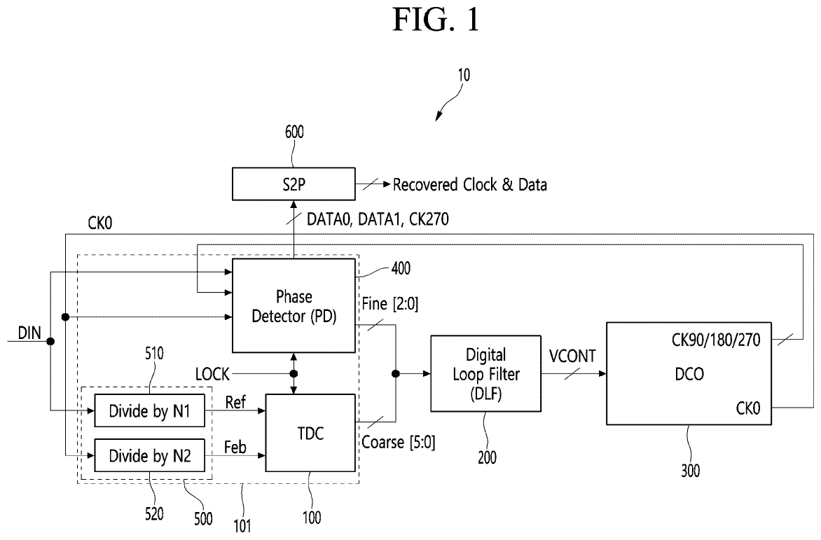

FIG. 1 is a block diagram illustrating a clock data recovery device according to an example aspect of the present disclosure.

Referring to FIG. 1, the clock data recovery device 10 may include a phase difference compensation unit 101, a digital loop filter 200, and a digital controlled oscillator 300 (DCO).

The phase difference compensation unit 101 may output an upper bit value (COARSE [5:0]) and a low bit value (FINE [2:0]) for a phase difference between a first input signal DIN and a second input signal CK0, according to a condition based on a range of the phase difference value.

In an example aspect, the phase difference compensation unit 101 may include a time to digital converter (TDC) 100 and a phase detector (PD) 400, which optionally operate. Here, the phase detector 400 may also be referred to as a bang phase detector.

For example, when nine bits of data are used, the upper bit value may correspond to the value of upper six bits and the low bit value may correspond to the value of low three bits. In another example, the upper bit value may be the most significant bit (MSB) and the lower bit value may be the least significant bit (LSB). As an example, the upper bit value may be 3 MSB bits and the low bit value may be 6 LSB bits.

The digital loop filter 200 may generate a digital control code based on an error signal input. For example, the digital loop filter 200 may receive an output signal of the phase difference compensation unit 101 and output a control code (VCONT) accordingly.

The input signal may be input to the TDC 100 and the phase detector 400, and signals output respectively from the TDC 100 and the phase detector 400 may be input to the digital loop filter 200.

The digital controlled oscillator (DCO) 300 may transfer a feedback signal to the phase difference compensation unit 101 according to the output value (VCONT) of the digital loop filter 200.

For example, the digital controlled oscillator 300 may oscillate four signals with a phase difference of 90 degrees according to the output value VCONT of the digital loop filter 200. For example, the digital controlled oscillator 300 may oscillate a CK0 signal that is in zero phase, a CK90 signal that is 90 degrees out of phase with respect to CK0, a CK180 signal that is 90 degrees out of phase with respect to CK90, and a CK270 signal that is 90 degrees out of phase with respect to CK180.

In an example aspect, the digital controlled oscillator 300 may use a total of nine bits to control an oscillation frequency. The upper six bits may use a value compared by the TDC 100, and the lower three bits may use a value compared by the phase detector 400.

For example, when the phase of the reference signal Ref and the phase of the feedback signal Fed match each other within a certain level (course) in the TDC 100, the phase is locked (LOCK=H), the operation of the TDC 100 may be stopped, and the phase detector 400 may then be operated.

When the phase of the reference signal (Ref) and the phase of the feedback signal (Fed) deviates from within a certain level (course) after the phase is locked (LOCK=H), the phase may be again not locked (LOCK=L) and the TDC 100 may be again operated.

The phase difference compensation unit 101 may further include a divider unit 500 that divides the data signal (DIN) and the output signal (CK0) of the digital control oscillator.

The divider unit 500 may include a first divider 510 that divides the data signal DIN and a second divider 520 that divides the output signal CK0 of the digital controlled oscillator.

Here, for example, the reference signal Ref (first input signal) may be a signal obtained by dividing the input data signal DIN by the first divider 510. The feedback signal Fed (second input signal) may be a signal obtained by dividing the output signal CK0 of the digital control oscillator 300 by the second divider 520.

As described above, the input data signal DIN and the output signal CK0 of the digital controlled oscillator 300 may each be divided in the divider unit 500 and input to the TDC 100.

The TDC 100 may further include a serial to parallel converter (S2P) 600 connected to the phase detector 400, to which the recovered data is output. In such a serial to parallel converter 600, the recovered clock and data may be serialized and output.

As described above, the digital clock data recovery device 10 for recovering clock and data from a data signal according to the present disclosure may include a phase difference compensation unit 101 that selectively outputs an upper bit value and a lower bit value of a phase difference value between a first input signal and a second input signal according to a condition based on a range of the phase difference value, a digital loop filter DLF 200 that receives the output of the phase difference compensation unit 101, and a digital controlled oscillator DCO 300 that transfers a feedback signal to the phase difference compensation unit 101 based on the output of the digital loop filter 200.

As an example aspect, the digital clock data recovery device 10 for recovering clock and data from a data signal according to the present disclosure may include a TDC 100 that compares phases of a reference signal and a data signal and output a phase difference, a digital loop filter 200 to which the output value of the TDC 100 is input, a digital controlled oscillator 300 that oscillates a signal according to the output value of the digital loop filter 200, and a phase detector 400 that accumulates and outputs a number of the phase differences between the data signal and the output of the digital controlled oscillator.

In this case, the output of the digital controlled oscillator 300 may be input to the TDC 100 and the phase detector 400.

In other words, according to the output of the digital controlled oscillator 300, the TDC 100 may be operated in a first condition and the phase detector 400 may be operated in a second condition.

According to an aspect, the digital loop filter 200 may receive skew information from the TDC 100 and control the phase of a clock such that a clock oscillated by the digital control oscillator 300 and a reference clock signal Ref are locked.

The digital loop filter 200 may determine that a phase error signal is locked when the value of the phase error signal is dithering near “0”. For example, the digital loop filter 200 may receive a value where the clock is phase-leading or a value where the clock is phase-lagging from the TDC 100 and generate a DCO control code to provide to the digital controlled oscillator 300. According to an aspect, the digital controlled oscillator 300 may generate a variable frequency signal based on the digital control code received from the digital loop filter 200.

According to an aspect, the digital loop filter 200 may receive a phase error signal from the phase detector 400 and control the phase of a clock such that the data and the clock are locked. The digital loop filter 200 may determine that the phase error signal is locked if the value of the phase error signal is dithering near “0”. For example, the digital loop filter 200 may receive a value where the clock is phase-leading or a value where the clock is phase-lagging from the phase detector 400 and generate and provide a DCO control code to the digital controlled oscillator 300. According to an aspect, the digital controlled oscillator 300 may generate a variable frequency signal based on the digital control code received from the digital loop filter 200.

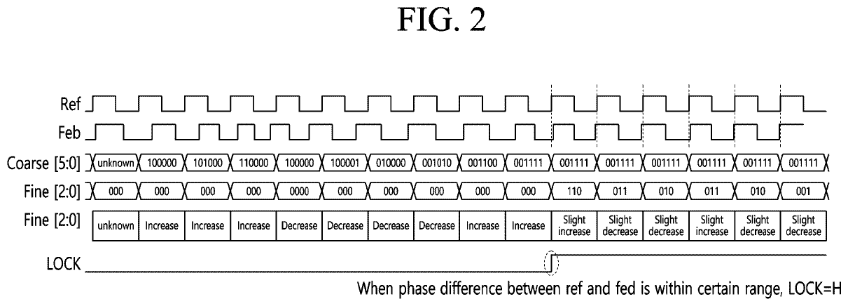

FIG. 2 is a timing diagram illustrating operation of a clock data recovery device according to an example aspect of the present disclosure.

The clock data recovery device 10 according to the present disclosure may operate with an embedded clock without a reference clock, and may be entirely implemented as a digital circuit. As described above, the absence of a reference clock may mean that a clock is embedded in data, and the clock may be extracted and used.

Initially, when the clock data recovery device 10 is operating, the digital controlled oscillator 300 may operate as a so-called quadrature DCO in which four input phases are output.

In this case, the output of the digital controlled oscillator 300 and the output of an input data signal may be divided and input to the time-to-digital converter TDC 100.

The TDC 100 may be a phase comparator and may require two inputs. Accordingly, the divider unit 500 may include a first divider 510 and a second divider 520.

These two dividers 510 and 520 may be added to allow for use with different protocols. Here, the first divider 510 may have a first dividing ratio N1, and the second divider 520 may have a second dividing ratio N2.

A signal input to the divider unit 500 may have one phase having a time of 4UI. Initially, the clock of the signal may be tuned. For example, when a signal is initially input, the signal may be compared with the least common multiple (LCM). In this comparison process, the rising edge of the signal may be compared.

The output signal of the TDC 100 or phase detector 400 may be input to the digital loop filter 200. The digital loop filter 200 may output an analog signal, VCONT.

The oscillation frequency of the digital controlled oscillator 300 may change according to the output signal VCONT of the digital loop filter 200. For example, the output signal may be 1.8 V.

Accordingly, the output signal is increased by, for example, 20 mV per step, and accordingly, the oscillation frequency increases.

In an aspect of the present disclosure, since the dividing ratio may be different depending on various protocols, two dividers 510 and 520 may be included to match the clock signal and the data signal.

Here, the first dividing ratio NI and the second dividing ratio N2 may be determined according to the specifications. For example, the divider unit 500 may be a programmable divider. Description will be given later with reference to the drawings.

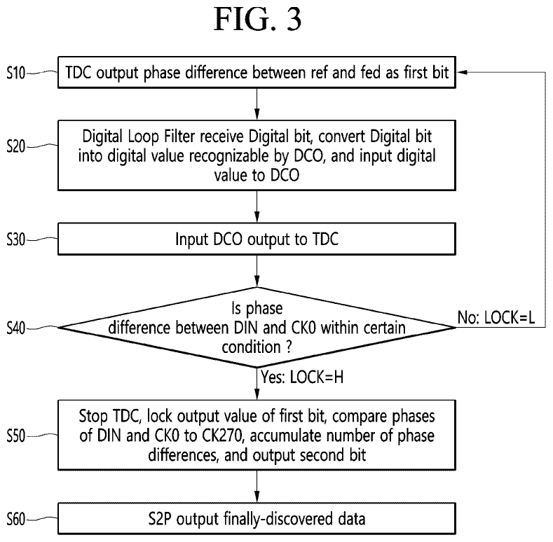

FIG. 3 is a flowchart showing the operation of a clock data recovery device according to an aspect of the present disclosure.

Hereinafter, the operation of the clock data recovery device 10 according to the aspect of the present disclosure will be described in a step-wise manner with reference to FIGS. 1 to 3.

First, an input data signal DIN may be divided and input to the TDC 100 or the phase detector 400 through the divider unit 500. As described above, the output of the digital controlled oscillator 300 may be input to the TDC 100 when a first condition is met, and may be input to the phase detector 400 when a second condition is met.

In this case, a data signal (reference signal) Ref that has passed through the first divider 510 when the first condition is met, and an output signal (feedback signal) Feb of the digital controlled oscillator 300 that has passed through the second divider 520 may be input to the TDC 100.

The TDC 100 may output a signal corresponding to the phase difference between the data signal (reference signal: Ref) and the output signal (feedback signal) Feb (S10).

Thereafter, the digital loop filter 200 may receive a signal (digital bit) from the TDC 100 and change the signal into a digital value that the digital controlled oscillator 300 is able to recognize. The digital value VCONT changed as described above may be input to the digital controlled oscillator 300 (S20).

Next, the digital controlled oscillator 300 may oscillate four signals with a phase difference of 90 degrees according to the output value VCONT of the digital loop filter 200. For example, the digital controlled oscillator 300 may oscillate a CK0 signal that is in zero phase, a CK90 signal that is 90 degrees out of phase with respect to CK0, a CK180 signal that is 90 degrees out of phase with respect to CK90, and a CK270 signal that is 90 degrees out of phase with respect to CK180.

In this way, the output CK0 oscillated by the digital controlled oscillator 300 may be divided by the second divider 520 of the divider unit 500 and input to the TDC 100 (S30).

In this case, in the TDC 100, locking may be made when the phase difference between the reference signal Ref and the feedback signal Feb falls within a certain condition.

For example, the TDC 100 may adjust a time difference (phase difference) between two input signals Ref and Feb to within a certain condition. For example, the TDC 100 may adjust the time difference (phase difference) between two input signals Ref and Feb to within about 10%.

In the TDC 100, the upper bit value data COARSE of the phase difference value of the first input signal DIN and the second input signal CK0 may be output. For example, when 9-bit data is used, data ([5:0]) corresponding to the upper 6 bits may be compared in the TDC 100.

It may be determined whether the time difference (phase difference) between two inputs Ref and Feb, that is, between the first input signal DIN and the second input signal CK0, is within a certain condition (S40).

As described above, when the time difference (phase difference) between the two inputs Ref and Feb, i.e., between the first input signal DIN and the second input signal CK0, is within a certain condition (Yes: LOCK=H), the TDC 100 may output a lock signal (LOCK=H) and then stop operating.

The locking may be performed by a separate lock detector. For example, the lock detector may detect that a lock is made when the phases of the two input signals Ref and Feb are within the certain condition.

On the other hand, when the time difference (phase difference) between the two inputs Ref and Feb, i.e., between the first input signal DIN and the second input signal CK0, is out of the certain condition (No: LOCK=L), the operation described above may be performed in the TDC 100. That is, a signal corresponding to the phase difference between the data signal (reference signal) Ref and the output signal (feedback signal) Feb may be output (S10).

In this way, when the time difference (phase difference) between the two inputs Ref and Feb, i.e., between the first input signal DIN and the second input signal CK0, is within the certain condition (Yes: LOCK=H), the TDC 100 may stop operating, or the output value may be locked to a certain value. Further, the phase of the first input signal DIN and the phases of the second input signals CK0 to CK270 may be compared (S50) in the phase detector 400.

For example, the phase detector 400 may compare the phase between the first input signal DIN and the phases of the second input signals CK0 to CK270 and accumulate and output the number of phase differences.

The phase detector 400 may compare the phases between the first input signal DIN and the second input signals CK0 to CK270 and output the lower bit value by comparing them.

For example, when 9 bits of data are used, 3 bits ([2:0]) of data may be output from the phase detector 400.

FIG. 2 illustrates the increasing and decreasing state of the output signal VCONT of the digital loop filter 200 during the above-described process.

The TDC 100 may compare only clock training patterns without comparing data. The actual data may be compared in the phase detector 400. For example, the phase detector 400 may detect the phase of data after locking.

The final recovered data may then be serialized and output via a serial to parallel converter 600 (S60).

In the divider unit 500, the dividing ratio N1 (2) and N2 (5) is set to a minimum common multiple to allow the TDC 100 to compare the two signals at same timing.

Aspects of the present disclosure are digitally implemented, so any protocol may be used. For example, the speeds may be the same for the same digital configuration.

Further, according to aspects of the present disclosure, a clock embedded signal without a reference clock is used, which may reduce the number of output pins when the aspect is implemented as an integrated circuit (IC).

According to aspects of the present disclosure, the locking of the signal is performed by the TDC 100 and the phase detector 400 so that the locking may be performed in a short time.

For example, among 9 bits of data, the upper bit values (6 MSBs representing larger number of units) may be determined by the TDC 100, while the remaining lower bit values (3 LSBs representing smaller number of units) may be determined by the phase detector 400.

In the conventional art, since phase noise is determined depending on the resolution of the TDC, it is necessary to increase the resolution of the TDC, which increases the size of the TDC circuit. On the other hand, in the case that the resolution of the TDC is low, a phase error between the clock and output of the divider increases, resulting in poor phase noise characteristics. In the case that a phase detector is used instead of a TDC, the TDC circuit may be reduced, but the locking time may be increased.

However, according to an aspect of the present disclosure, it is possible to implement a clock data recovery device capable of operating with a signal with an embedded clock without a reference clock as a fully digital circuit. As described above, the clock data recovery device may be implemented as a digital circuit, which has the advantage of short locking time. Furthermore, it is highly scalable to process changes.

As described above, it is possible to configure a divider capable of changing a dividing ratio between an input path and a feedback path, respectively, which may be used in different protocols.

On the other hand, to increase resolution, for example, a total of 9 bits of data may be used, but the TDC 100 may be implemented with only the upper bits (e.g., 6 bits), thereby reducing the size of the circuit.

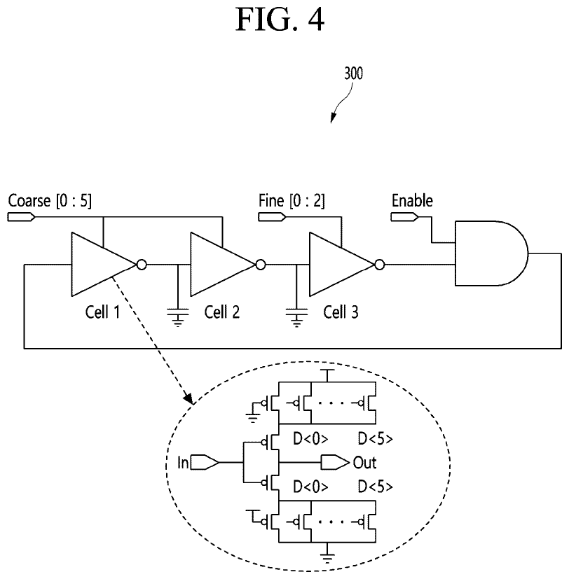

FIG. 4 is a block diagram illustrating a digital controlled oscillator of a clock data recovery device according to an example aspect of the present disclosure.

Referring to FIG. 4, a digital controlled oscillator (DCO) 300 may include a plurality of cells Cell 1, Cell 2, and Cell 3.

A coarse code or fine code may regulate a current value inside an inverter cell. The delay of the inverter cell may be shorter when a drive current increases and longer when the drive current decreases. In this case, the shorter delay of the inverter cell may result in a higher oscillation frequency, and the longer delay may result in a lower frequency.

According to the present aspect, the digital controlled oscillator 300 may include first cells Cell 1 and Cell 2 corresponding to upper bit values and a second cell Cell 3 corresponding to a lower bit value. In this case, the number of first cells Cell 1 and Cell 2 may be greater than the number of second cell Cell 3.

Since there are two cells (first cells) receiving the coarse code and one cell (second cell) receiving the fine code, the amount of oscillation frequency change due to the coarse code may be greater than the amount of oscillation frequency change due to the fine code.

The frequency CK0 of the digital controlled oscillator 300 may change continuously. For example, when the voltage increases, the frequency increases as well. In other words, the voltage may operate in proportion to the frequency. In the case that the frequency is low, the voltage may be increased. In this process, the voltage may be increased to make the two output voltages equal. This loop operation may be referred to as a phase loop lock (PLL) process.

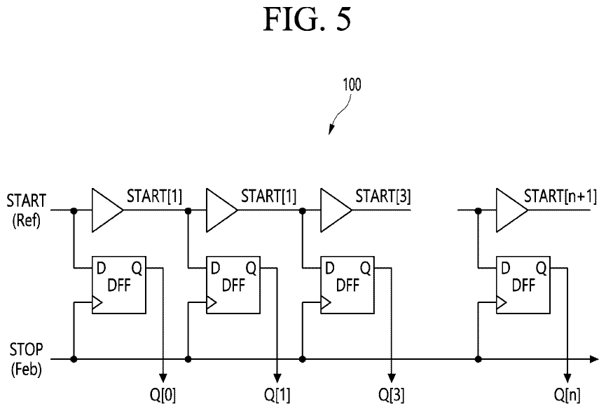

FIG. 5 is a block diagram illustrating a TDC of a clock data recovery device according to an example aspect of the present disclosure.

According to an aspect, the TDC 100 may receive a reference clock signal Ref and a divided clock signal from the digital controlled oscillator 300. The TDC 100 may detect a time difference by comparing the reception time points of the reference clock signal Ref and the divided clock signal.

For example, the TDC 100 may generate skew information to indicate the time difference. For example, the TDC 100 may receive the reference clock signal Ref at a first time point, and receive the divided clock signal from the digital controlled oscillator 300 at a second time point that is later than the first time point. In this case, the TDC 100 may determine how many clocks have passed between the first time point and the second time point according to the reference clock signal, and generate the skew information.

The TDC (Time to Digital Converter) 100 may compare the positions of the rising edges of a START signal Ref and a STOP signal Feb.

When the START signal Ref leads the STOP signal Feb, the CLK (=STOP) of the DFF catches High, so that Q=H.

Conversely, when the START signal Ref lags the STOP signal Feb, then Q=L.

However, a buffer delay may be added only to the path of the START signal Ref. Accordingly, assuming that the START signal Ref initially leads the STOP signal Feb by 500 ps and the buffer delay is 200 ps, Q[0]=H, Q[1]=H Q[2]=H, Q[3]=L . . . may result.

In this case, the number of Hs in the Q values may be used to digitally determine how much the START signal Ref leads the STOP signal Feb.

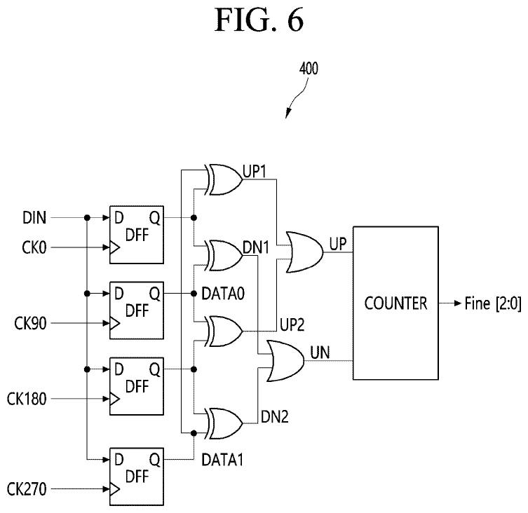

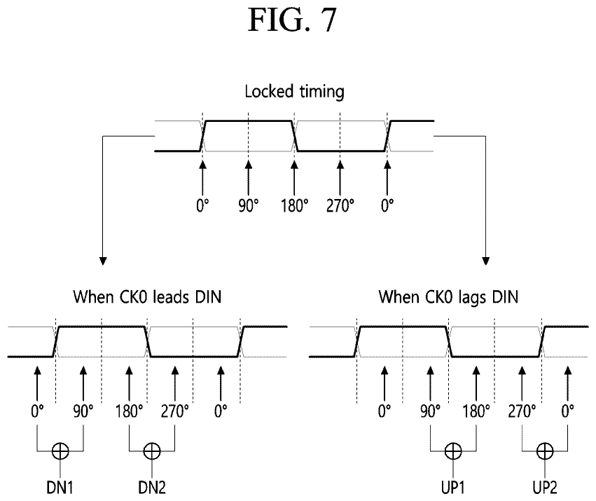

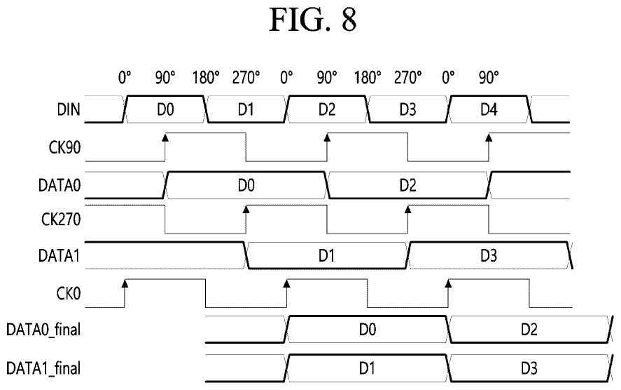

FIG. 6 is a block diagram showing a phase detector of a clock data recovery device according to an example aspect of the present disclosure. FIG. 7 and FIG. 8 are timing diagrams for describing the operation of the phase detector.

Referring to FIG. 6, according to an aspect, the phase detector 400 may receive a signal from a comparison sampler (not shown) and then determine whether data and a clock match or whether the clock leads/lags the data. The phase detector 400 may determine locking of the clock or whether the clock leads/lags the data based on changes in the output values of the comparison sampler (not shown) received during a predefined unit interval (UI).

The phase detector 400 may include a first XOR gate and a second XOR gate. The output of the first XOR gate may be a signal for indicating that the clock leads the data. The output of the second XOR gate may be a signal indicating that the clock lags the data. The first XOR gate and the second XOR gate may generate an output indicating that the clock leads the data or the data leads the clock by comparing the data of the falling edge DN of the clock and the rising edges UP of the clock located on both ends of the falling edge.

In other words, the phase detector 400 may compare the phases of the input signal DIN and the oscillation signal CK0. In the case that the rising edge of the input signal DIN leads CK0, the phase detector 400 may raise the UP signal to ‘H’ (at this time, DN=‘L’), and in the case that the rising edge of the input signal DIN lags CK0, raise the DN signal to ‘H’ (at this time, UP=‘H’).

In this case, the COUNTER may compare the number of UPs and the number of DNs, and in the case that the number of UPs is greater than the number of DNs, Fine [2:0] increases to a higher number, and in the case that the number of UPs is less than DN, the Fine [2:0] counter number decreases.

FIG. 7 illustrates the principle of generating UP/DN signals in a phase detector. Referring to FIG. 7, there is shown a process of generating DN and UP, respectively.

FIG. 8 shows signals input to a serial to parallel converter. Referring to FIG. 8, the relative phases of an input signal DIN, oscillation signals CK90 and CK270, and DATA0 and DATA1 generated by the phase detector 400 are shown. Also shown are the relative phases of final data DATA0 and DATA1 generated by the phase detector 400.

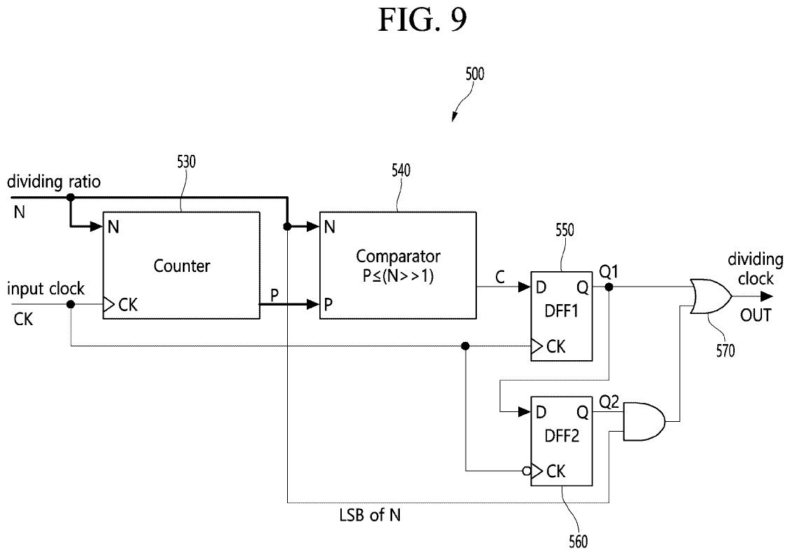

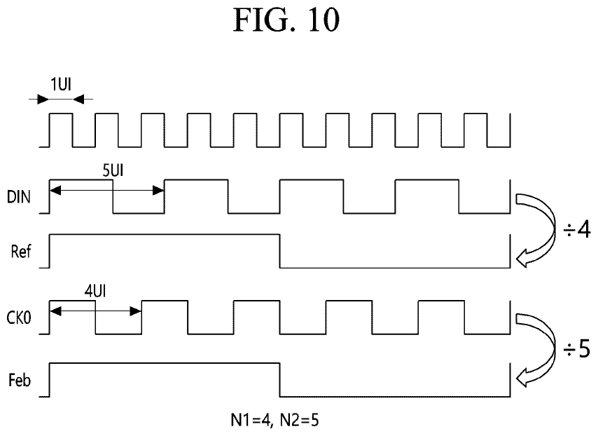

FIG. 9 is a block diagram illustrating a divider unit of a clock data recovery device according to an example aspect of the present disclosure. FIGS. 10 to 12 are timing diagrams of a divider unit.

According to an aspect of the present disclosure, the divider unit 500 may include two dividers 510, 520 for use with various protocols. Here, the first divider 500 may have a first dividing ratio N1 and the second divider 520 may have a second dividing ratio N2.

A signal input to the divider unit 500 may have one phase having a time of 4UI. Initially, the clock of the signal may be tuned. For example, when a signal is initially input, the signal may be compared with the least common multiple (LCM). During this comparison, the rising edges of the signals may be compared.

In an aspect of the present disclosure, since the dividing ratio may be different depending on various protocols, two dividers 510 and 520 may be included to match the clock signal and the data signal.

Here, the first dividing ratio NI and the second dividing ratio N2 may be determined according to the specifications. In an example, the divider unit 500 may be a programmable divider.

FIG. 10 is a timing diagram when an embedded-clock has a period of 5 UI. In this case, the first dividing ratio NI and the second dividing ratio N2 may be 4 and 5, respectively.

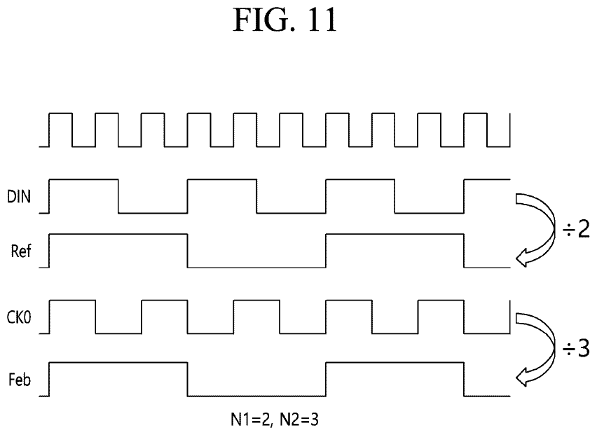

FIG. 11 is a timing diagram when the period of an embedded-clock is 6 UI. In this case, the first dividing ratio NI and the second dividing ratio N2 may be 2 and 3, respectively.

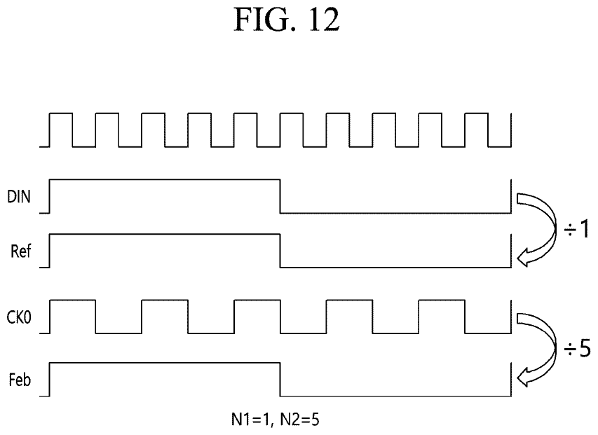

FIG. 12 is a timing diagram when the period of an embedded-clock is 20 UI. In this case, the first dividing ratio N1 and the second dividing ratio N2 may be 1 and 5, respectively.

These first dividing ratio N1 and second dividing ratio N2 may be externally input when the signal is determined.

According to an aspect of the present disclosure, the above-described method may be implemented with codes readable by a processor on a medium in which a program is recorded. Examples of the medium readable by the processor include a ROM (Read Only Memory), a Random Access Memory (RAM), a CD-ROM, a magnetic tape, a floppy disk, an optical data storage device, and the like, and may be implemented in the form of a carrier wave (for example, transmission through the Internet).

The digital clock data recovery device as described in the present disclosure is not limited to the configuration and method of the above-described aspects, but the aspects may be configured by selectively combining all or part of each aspect such that various modifications may be made. Thus, it is intended that the present disclosure covers the modifications and variations of the aspects provided they come within the scope of the appended claims and their equivalents.

What is claimed is:

1. A digital clock data recovery device for recovering a clock and data in a data signal, comprising:
a phase difference compensation unit configured to selectively output an upper bit value and a lower bit value of a phase difference value between a first input signal and a second input signal according to a condition based on a range of the phase difference value;
a digital loop filter configured to receive an output of the phase difference compensation unit; and
a digital controlled oscillator configured to transfer a feedback signal to the phase difference compensation unit based on an output value of the digital loop filter.

2. The digital clock data recovery device of claim 1, further comprising a divider unit configured to divide the data signal and an output signal of the digital control oscillator.

3. The digital clock data recovery device of claim 2, wherein the divider unit includes:
a first divider configured to divide the digital signal; and
a second divider configured to divide the output signal of the digital controlled oscillator.

4. The digital clock data recovery device of claim 3, wherein the first input signal and the second input signal are input respectively through the first divider and the second divider.

5. The digital clock data recovery device of claim 1, wherein a magnitude of the upper bit value is greater than a magnitude of the lower bit value.

6. The digital clock data recovery device of claim 1, wherein the digital controlled oscillator includes:
first cells corresponding to the upper bit value; and
second cells corresponding to the lower bit value.

7. The digital clock data recovery device of claim 6, wherein a number of the first cells is greater than a number of the second cells.

8. The digital clock data recovery device of claim 1, wherein the phase difference compensation unit includes:
a Time to Digital Converter (TDC) configured to operate under a first condition, receive the first input signal and the second input signal, and output an upper bit value of a phase difference value between the first input signal and the second input signal; and
a phase detector configured to operate under a second condition, receive the first input signal and the second input signal, and output a lower bit value of the phase difference value between the first input signal and the second input signal.

9. The digital clock data recovery device of claim 8, further comprising a serial to parallel converter connected to the phase detector, to which recovered data is output.

10. A digital clock data recovery device for recovering a clock and data in a data signal, comprising:
a Time-to-Digital Converter (TDC) configured to compare phase differences between a reference signal and data signals to output a first bit value;
a digital loop filter configured to receive an output value of the TDC;
a digital controlled oscillator configured to oscillate a signal according to an output value of the digital loop filter; and
a phase detector configured to accumulate a number of phase differences between the data signal and an output of the digital controlled oscillator and output a second bit value.

11. The digital clock data recovery device of claim 10, wherein the first bit value is an upper bit value, and the second bit value is a lower bit value.

12. The digital clock data recovery device of claim 10, further comprising a divider unit configured to divide the data signal and an output signal of the digital control oscillator.

13. The digital clock data recovery device of claim 12, wherein the divider unit includes:
a first divider configured to divide the digital signal; and
a second divider configured to divide a signal of the digital controlled oscillator.

14. The digital clock data recovery device of claim 10, further comprising a serial to parallel converter connected to the phase detector, to which recovered data is output.

15. The digital clock data recovery device of claim 14, wherein the phase detector is configured to accumulate and output a number of a phase difference between the digital signal and an output of the digital controlled oscillator.
